(19) United States
(12) Patent Application Publication
(10) Pub. No.: US 2017/0075395 A1
(43) Pub. Date: Mar. 16, 2017

(54) SOLID COOLING ARRANGEMENT FOR ELECTRONIC DEVICE

(71) Applicant: Li Qingyuan, Beijing (CN)

(72) Inventor: Li Qingyuan, Beijing (CN)

(21) Appl. No.: 15/199,943

(22) Filed: Jun. 30, 2016

Related U.S. Application Data
(63) Continuation-in-part of application No. 14/852,495, filed on Sep. 12, 2015, now Pat. No. 9,405,336.

(51) Int. Cl. G06F 1/20; G06F 1/18; H05K 7/20

(52) U.S. Cl. CPC G06F 1/20; H05K 7/20172; H05K 7/2039; G06F 1/185; G06F 1/189

(57) ABSTRACT

The present disclosure provides a electronic device having quiet cooling, to improve heat dissipation efficiency and increase space utilization. The present disclosure comprising circuit boards, fixer(s), cooling elements installed around the outside surfaces of said circuit boards. The present disclosure further comprising joint cooling fan for hours of compute intensive tasks.

### RELATED APPLICATION

This is a continuation-in-part of U.S. patent application Ser. No. 14/852,495 filed on Sep. 12, 2015, now U.S. Pat. No. 9,405,336.

### FIELD OF INVENTION

The present invention relates, in general, to solid cooling arrangement to be utilized for electronic components.

### BACKGROUND OF INVENTION

Conventional computers are very noisy devices. The main source of the noise generated is the cooling fan in the computer housing. The noise of the airflow and the mechanical vibration of the fan form a main part of the loud noise, which is highly undesirable.

The noise emitted by a personal computer in either a home or office is distracting and annoying, and can have negative effects on the productivity of the users. Also, the loud noise can interfere with activities such as listening to music or sleeping.

Liquid cooling systems are getting more and more popular. But the liquid cooling systems are still quite noisy because it requires pump to circulate the liquid.

What is needed is an operable computer with lowest use of mechanical fans or pumps. Such a computer would be expected to operate quieter, to be more compact than current models, and to have enhanced reliability without any substantial cost penalty.

Such a computer is described in U.S. Pat. No. 5,671,120, in which one side of the housing is configured to be a cooling body. But it is not the face (of motherboard) with CPU installed being mounted to the cooling body, so the heat sink will not have direct contact with high thermal dissipating object. It is not efficient for cooling.

U.S. Pat. No. 8,582,298 B2 shows a computer with two sides of the housing configured to be cooling bodies. But it is designed for data center. It requires a customized motherboard to fit around the heat pipes. It could utilize only two smaller faces around the PCB (Printed Circuit Board) to install heat sinks because of high-density server environment.

U.S. Pat. No. 6,867,985 B2 shows a passively cooled computer with cooling ribs pointing outwards. A motherboard is arranged in between cooling ribs, with processor and hard disk drives being pressed against one of the cooling bodies. It is not easy to increase storage volume, because the hard disk drives are coupled with the processor and the cooling bodies.

U.S. Pat. No. 7,072,179 B1 describes a computer with integrated display. The back side of the housing is configured to be a cooling body. But the heat sink is enclosed in a closed box and it is not efficient to dissipate the waste heat.

### SUMMARY OF INVENTION

Problems of the prior art:
A typical ATX computer case put all mechanical fan(s) inside the enclosure, which make the chassis very cumbersome and have limitations on the size of heat sink.
A typical graphics card is installed perpendicularly to the motherboard PCB (Printed Circuit Board), which limits the height of the heat sink on graphics card to less than a couple of PCI slots.

Therefore, in accordance with all embodiments of the invention there are provided cooling arrangement, comprising:
Circuit boards, for example, motherboard, graphics card(s).
Adapter(s) to electrically connect and mechanically fixate the circuit boards;
Fixer(s) to mechanically support and fixate the circuit boards;
The circuit boards, the adapter(s) and the fixer(s) assembling to shape into geometric solid (e.g. prism, pyramid), so cooling elements could be installed around the outside of the geometric solid.
Optional joint cooling fan(s) having hole to allow data/power cables get through and coupled to the circuit boards.

It should be understood, however, that this summary may not contain all aspects and embodiments of the present invention, that this summary is not meant to be limiting or restrictive in any manner, and that the invention as disclosed herein will be understood by one of ordinary skill in the art to encompass obvious improvements and modifications thereto.

### BRIEF DESCRIPTION OF DRAWINGS

FIG. 1 is an exploded view of one exemplary embodiment of the present invention, having 2 circuit boards (1 motherboard and 1 graphics card).

FIG. 2 is a perspective view of another exemplary embodiment of the present invention, having 3 circuit boards (1 motherboard and 2 graphics cards) and a joint cooling fan.

FIG. 3 is an exploded view of one exemplary embodiment of the joint cooling fan in FIG. 2, which comprises a cooling fan, a fan axle, a fan motor base and protective frame.

FIG. 4 is an part view of yet another exemplary embodiment of the present invention, having 4 circuit boards (1 motherboard and 3 graphics cards) assembled to shape a pyramid.

In accordance with common practice, the various described features are not drawn to scale and are drawn to emphasize features relevant to the present disclosure. Like reference characters denote like elements throughout the figures and text.

### DETAILED DESCRIPTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

It will be understood that the term “and/or” includes any and all combinations of one or more of the associated listed items. It will also be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present invention.

It will be understood that various changes can be made in the function and arrangement of elements without departing from the spirit and scope as set forth in the appended claims. Accordingly, an embodiment is an example or implementation of the inventions and not the sole implementation. Various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention can also be implemented in a single embodiment or any combination of embodiments.

Reference in the specification to “one embodiment”, “an embodiment”, “some embodiments” or “other embodiments” means that a particular feature, structure, or characteristic described in connection with the embodiments is included in at least one embodiment, but not necessarily all embodiments, of the inventions. It is to be understood that where the specification states that a component feature, structure, or characteristic “may”, “might”, “can” or “could” be included, that particular component, feature, structure, or characteristic is not required to be included.

Reference to terms such as “left”, “right”, “top”, “bottom”, “front” and “back” are intended for use in respect to the orientation of the particular feature, structure, or element within the figures depicting embodiments of the invention. It would be evident that such directional terminology with respect to the actual use of a device has no specific meaning as the device can be employed in a multiplicity of orientations by the user or users.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

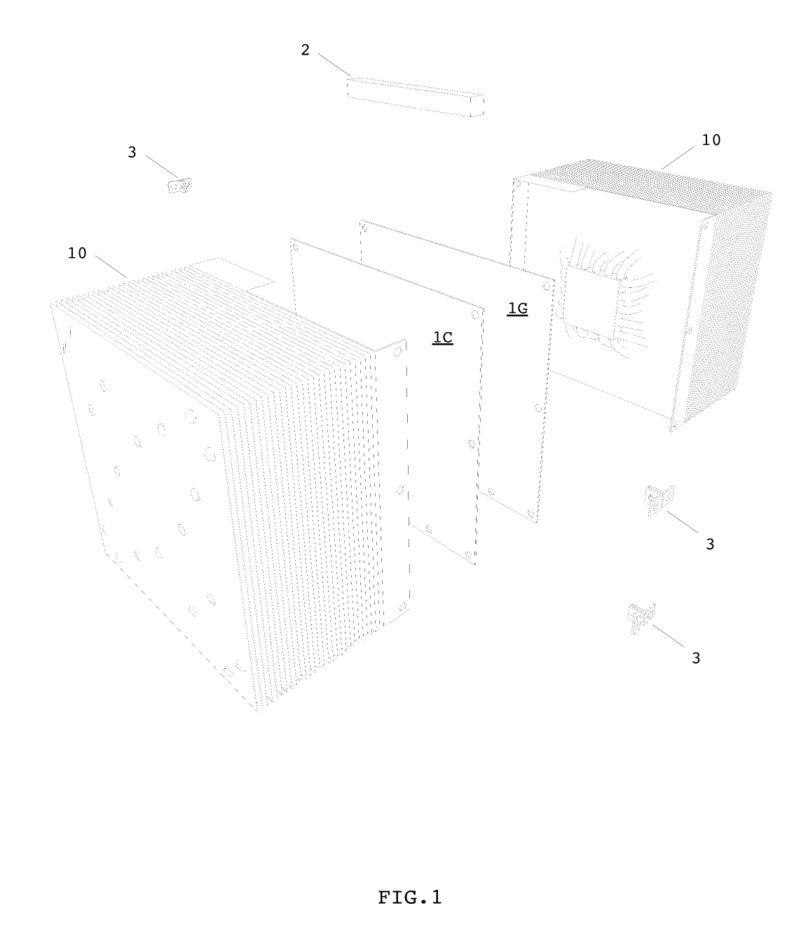

The description will be made as to the embodiments of the present invention in conjunction with the accompanying drawings in FIG. 1 to 5. Reference will be made to the drawing figures to describe the present invention in detail, wherein depicted elements are not necessarily shown to scale and wherein like or similar elements are designated by same or similar reference numeral through the several views and same or similar terminology.

The drawings shows computer cooling systems. Embodiments of the invention, however, are not limited to the application of computer cooling. For example, electronic devices as game console, could also utilize cooling arrangement described below.

ATX specification was developed by Intel in 1995. It was the first major change in desktop computer enclosure, motherboard and power supply design for 20 years. But after floppy disk drive (FDD) has been obsolete in early 21st century, and optical disc drive (ODD) has been almost superseded by USB flash drives and cloud storages, and solid-state drive (SSD) has been starting to replace hard disk drive (HDD), conventional ATX computer case with multiple 5.25″ and 3.5″ bays looks more and more unnecessary cumbersome. It is time to make another major change for desktop computers.

This trend has been started by Apple Mac mini and Intel NUC (Next Unit of Computing). Unfortunately, for these small form factor (SFF) desktop computer, the trade-off is that hardware specifications and processing power are usually reduced and hence make them less appropriate for running complex, resource-intensive applications.

To summarize, these SFF desktop computers are designed to minimize the volume of a desktop computer. They are not designed to eliminate noise. SFF are usually quieter just because they consume much less power and produce much less performance and much less heat. SFF will never make mainstream desktop computers under the current state of the art.

What is needed is a passive cooled computer having mainstream performance, so the key is to increase surface areas of heat sink(s) and improve the heat dissipation efficiency.

Meanwhile, even for a full-sized ATX computer case, the max height of heat sink on CPU is mostly limited to about the width of 5.25″ bays. The first object of the present invention is to remove this limitation, which will be introduced below.

A heat sink is one kind of cooling element which aids in the transfer of heat away from a high thermal dissipating object. A heat sink may be made of an element that is conductive to heat such as aluminum or copper. Heat sinks typically have fins that extend from the base. Fins extend the areas of the heat sink to allow more contact area for cooling air. Fins allow air to flow through the heat sink to enable more heat to be removed from the heat sink. Depending on fin spacing and geometry, the fins can be cooled in natural convection mode, driven by the buoyancy effects of air as it heats with respect to gravity; or through forced air cooling, such as the case of fans blowing cool air through the heated fin surface areas. The fins can be made of aluminum or copper, for example, and/or may be enhanced with graphite fibers. Heat can be spread between fins through soil base materials such as copper, but can be enhanced through the use of heat pipes.

A heat pipe is a component which aids in removing heat away from the heat sink. It transfer heat from one point to another. Often referred to as a superconductor, a heat pipe possesses extraordinary heat transfer capacity and rate with almost no heat loss. A heat pipe is made of an aluminum or copper container, and the container comprises inner surfaces having a capillary wicking material. Heat pipes utilize phase change within a closed container, where heat is vaporized at the evaporator section near the high thermal dissipating object, and condensed in the condenser section near the cooling fins. Liquid within the heat pipe then returns to the evaporator section through gravity assist, or more typically, via a wick material.

Liquid cooling is another kind of cooling element which aids in the transfer of heat away from a high thermal dissipating object. Most exemplary embodiments of the invention show heat sinks as exemplary cooling elements, however, the specific technology of cooling element, is not limited to the application of heat pipe or liquid cooling. For example, thermoelectric cooling, could also be utilized to build cooling element.

FIG. 1 shows an exploded view of one exemplary embodiment of the present invention, which has two circuit boards (one motherboard 1C and one graphics card 1G), electrically connected by adapter 2, mechanically supported and fixated by fixer(s) 3. The circuit boards 1C/1G, adapter 2 and fixer(s) 3 is assembled to shape into a geometric solid (hexahedron), so cooling elements (heat sinks) 10 could be installed around the outside of the hexahedron.

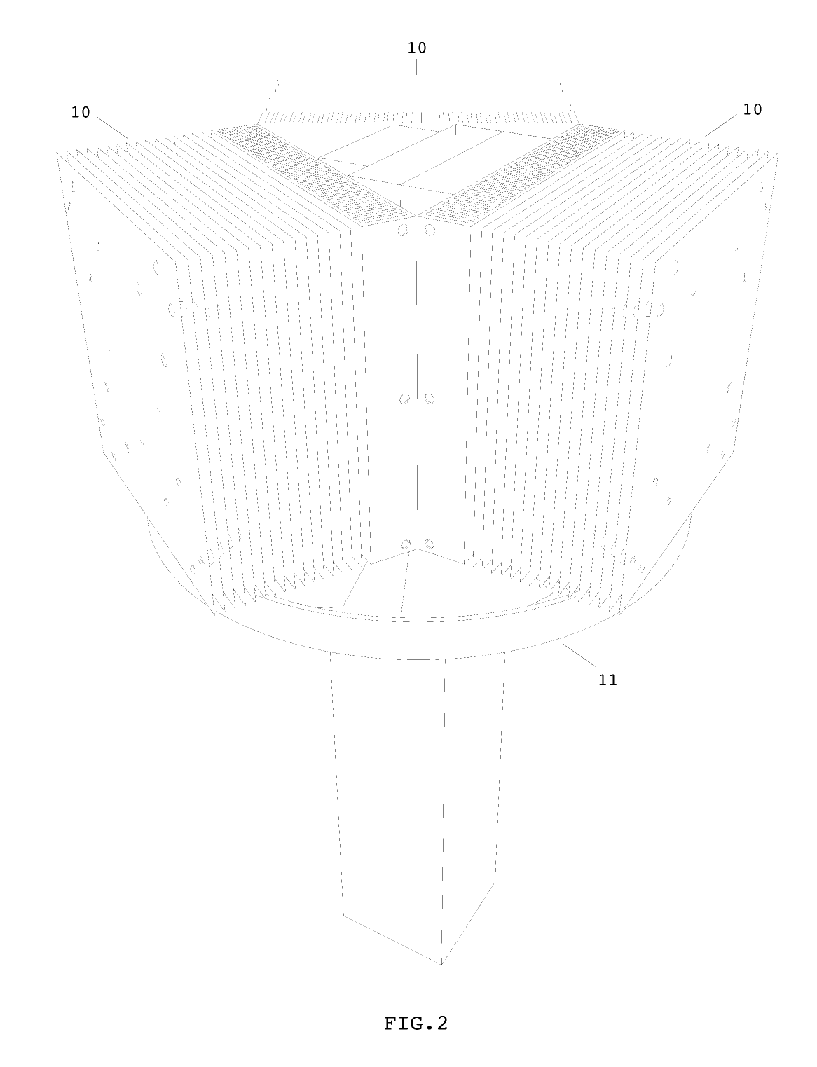

FIG. 2 shows a perspective view of another exemplary embodiment of the present invention, which has three circuit boards (one motherboard and two graphics cards), assembled with adapters and fixers to shape into a geometric solid (prism), so cooling elements (heat sinks) 10 could be installed around the outside of the prism.

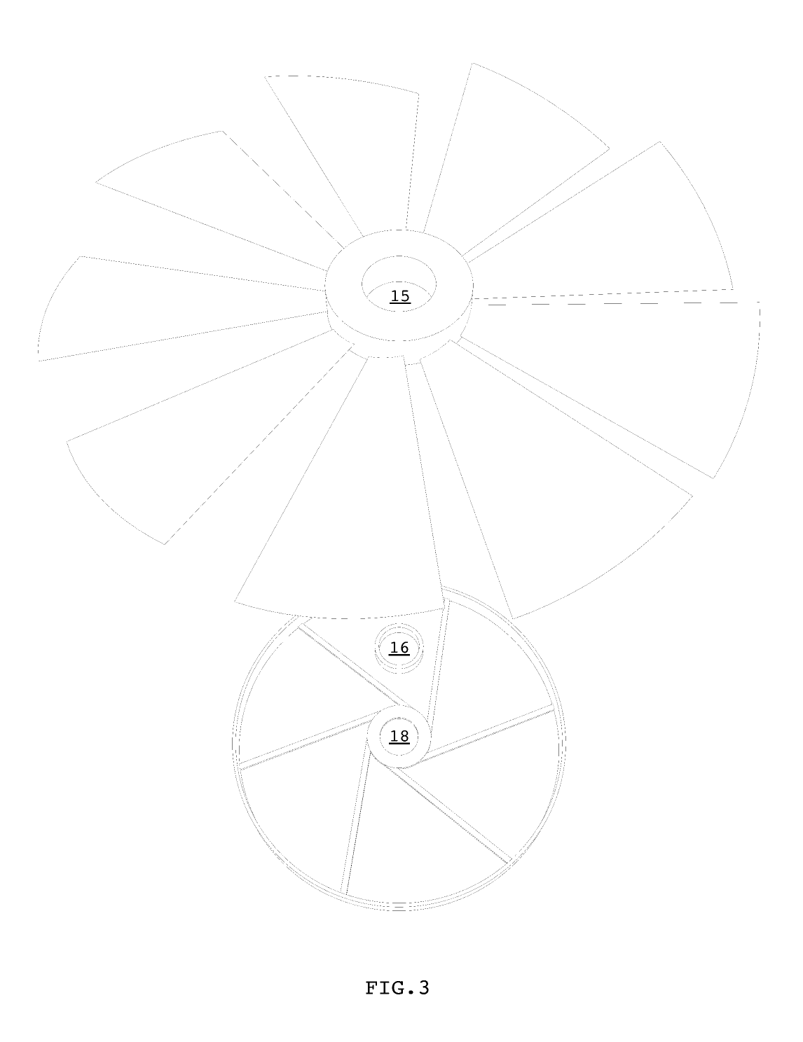

FIG. 3 is an exploded view of one exemplary embodiment of the joint cooling fan in FIG. 2, which comprises a cooling fan, a fan axle, a fan motor base and protective frame, the cooling fan, the fan axle, the fan motor and protective frame each has a hole to allow data/power cables get through and coupled to the circuit boards.

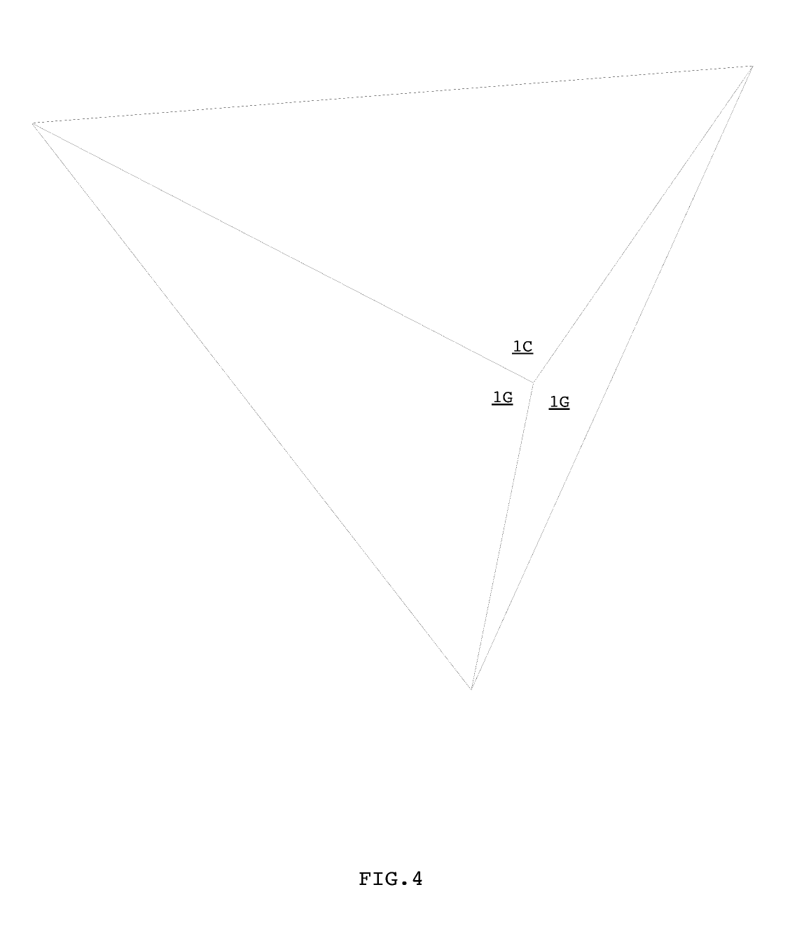

FIG. 4 is an part view of yet another exemplary embodiment of the present invention, which has four circuit boards (one motherboard 1C and three graphics cards 1G), assembled with adapters and fixers to shape into a geometric solid (pyramid), so cooling elements could be installed around the outside of the pyramid.

Previous descriptions are only embodiments of the present invention and are not intended to limit the scope of the present invention. Many variations and modifications according to the claims and specification of the disclosure are still within the scope of the claimed invention. In addition, each of the embodiments and claims does not have to achieve all the advantages or characteristics disclosed. Moreover, the abstract and the title only serve to facilitate searching patent documents and are not intended in any way to limit the scope of the claimed invention.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

I claim:

1. A electronic device having quiet cooling, comprising:
circuit boards, fixer(s), cooling elements installed around the outside surfaces of said circuit boards.

2.

3. The electronic device having quiet cooling according to claim 1, wherein the fixer mechanically supports and fixates said circuit boards.

4. The electronic device having quiet cooling according to claim 1, wherein the cooling element aids in the transfer of heat away from high thermal dissipating object(s) on said circuit boards.

5. A electronic device having quiet cooling, comprising:
circuit boards, fixer(s), joint cooling fan(s), cooling elements installed around the outside of said circuit boards.

6.

7. The electronic device having quiet cooling according to claim 5, wherein the fixer mechanically supports and fixates said circuit boards.

8. The electronic device having quiet cooling according to claim 5, wherein the cooling element aids in the transfer of heat away from high thermal dissipating object(s) on said circuit boards.

9. The electronic device having quiet cooling according to claim 5, wherein the joint cooling fan has a hole to allow data/power cables get through and coupled to said circuit boards.

10. A electronic device having quiet cooling, comprising:
circuit boards, fixer(s), joint cooling fan(s), cooling fan switch(es), cooling elements installed around the outside of said circuit boards.

11. The electronic device having quiet cooling according to claim 10, wherein the fixer mechanically supports and fixates said circuit boards.

12. The electronic device having quiet cooling according to claim 10, wherein the cooling element aids in the transfer of heat away from high thermal dissipating object(s) on said circuit boards.

13. The electronic device having quiet cooling according to claim 10, wherein the joint cooling fan has a hole to allow data/power cables get through and coupled to said circuit boards.
